(19) United States
(12) Patent Application Publication
(10) Pub. No.: US 2015/0069569 A1
(43) Pub. Date: Mar. 12, 2015

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Yusuke OKUMURA, Mie-ken (JP); Naoki KAI, Mie-ken (JP)

(73) Assignee: Kabushiki Kaisha Toshiba, Minato-ku (JP)

(21) Appl. No.: 14/177,550

(22) Filed: Feb. 11, 2014

Related U.S. Application Data
(60) Provisional application No. 61/874,558, filed on Sep. 6, 2013.

(51) Int. Cl. H01L 29/06; H01L 21/762

(52) U.S. Cl. CPC H01L 29/0649; H01L 21/76224
USPC 257/506; 438/424

(57) ABSTRACT

According to one embodiment, a semiconductor memory device includes: a first semiconductor region extending in a first direction; second semiconductor regions extending in a second direction crossing the first direction from the first semiconductor region and arranged in the first direction; and a first element isolation region provided between the second semiconductor regions. A width of the first semiconductor region in the second direction is wider than a width of the second semiconductor region in the first direction.

### CROSS-REFERENCE TO RELATED APPLICATIONS

This application is based upon and claims the benefit of priority from U.S. Provisional Patent Application 61/874,558, filed on Sep. 6, 2013; the entire contents of which are incorporated herein by reference.

### FIELD

Embodiments described herein relate generally to a semiconductor memory device and a method for manufacturing the same.

### BACKGROUND

The shrinking of a memory cell region of a nonvolatile semiconductor memory device is progressing more and more.

However, part of the mask pattern may fall down or divide according to shrinking of memory cell region. It is preferable to suppress such falling down and dividing of the mask pattern.

### BRIEF DESCRIPTION OF THE DRAWINGS

FIG. 1 is an example of a schematic plan view showing a pattern layout of part of a memory cell region of a nonvolatile semiconductor memory device according to an embodiment;

FIG. 2A and FIG. 2B are examples of schematic cross-sectional views of the nonvolatile semiconductor memory device of a nonvolatile semiconductor memory layer according to the embodiment;

FIG. 3A to FIG. 16B are examples of schematic views showing the manufacturing process of the nonvolatile semiconductor memory device according to the embodiment;

FIG. 17A to FIG. 18B are examples of schematic views showing the manufacturing process of a nonvolatile semiconductor memory device according to a comparative example; and

FIG. 19A to FIG. 20B are examples of schematic views showing effects of the manufacturing process of the nonvolatile semiconductor memory device according to the embodiment.

### DETAILED DESCRIPTION

In general, according to one embodiment, a semiconductor memory device includes: a first semiconductor region extending in a first direction; second semiconductor regions extending in a second direction crossing the first direction from the first semiconductor region and arranged in the first direction; and a first element isolation region provided between the second semiconductor regions. A width of the first semiconductor region in the second direction is wider than a width of the second semiconductor region in the first direction.

Hereinbelow, embodiments are described with reference to the drawings. In the following description, identical components are marked with the same reference numerals, and a description of components once described is omitted as appropriate.

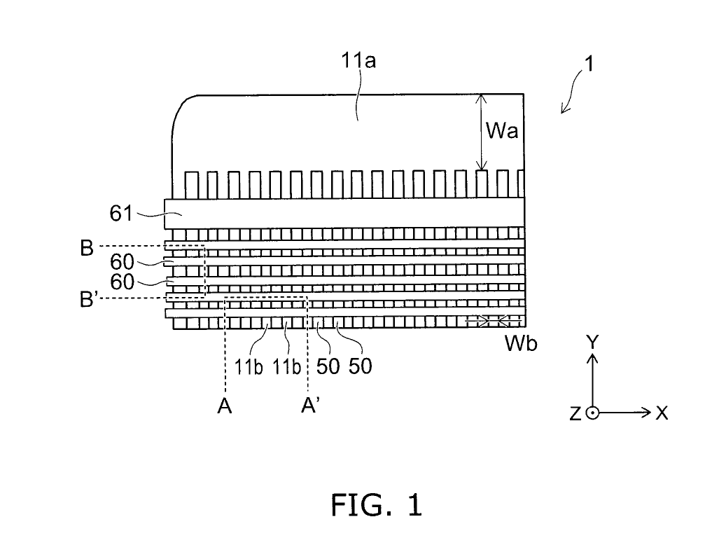

FIG. 1 is an example of a schematic plan view showing the pattern layout of part of a memory cell region of a nonvolatile semiconductor memory device according to an embodiment.

In a nonvolatile semiconductor memory device 1, a semiconductor region 11a extending in the X-direction and semiconductor regions 11b (element regions) extending in the Y direction from the semiconductor region 11a are provided. The semiconductor regions 11b are arranged in the X-direction. The width Wb of the semiconductor region 11b is smaller than the resolution limit by a lithography apparatus. An element isolation region 50 is provided between semiconductor regions 11b. The width Wa of the semiconductor region 11a is wider than the width Wb of the semiconductor region 11b. The spacing in the X-direction between semiconductor regions 11b is almost equal to the width Wb. In the Y-direction, the distances between the ends of the element isolation regions 50 and an end of the semiconductor region 11a on the opposite side to the semiconductor regions 11b are almost the same. In other words, the ends of the element isolation regions 50 may be aligned on an almost straight line in the X-direction.

Control gate electrodes 60 in a line shape are provided in the X-direction crossing the Y-direction to which the semiconductor region 11b extends. The control gate electrodes 60 are arranged in the Y-direction. The control gate electrodes 60 are provided on the upper side of the plurality of semiconductor regions 11b. A select gate electrode 61 having a line shape is provided adjacent to the control gate electrode 60.

In the nonvolatile semiconductor memory device 1, a transistor is disposed in a position where the semiconductor regions 11b and the control gate electrodes 60 cross each other (described later). The transistors are arranged two-dimensionally in the X-direction and the Y-direction. Each transistor functions as a memory cell of the nonvolatile semiconductor memory device 1.

Each of the semiconductor regions 11b forms part of a NAND string. the semiconductor regions 11b are electrically isolated by the element isolation regions 50 and the control gate electrodes 60. The control gate electrode 60 may be referred to as a word line.

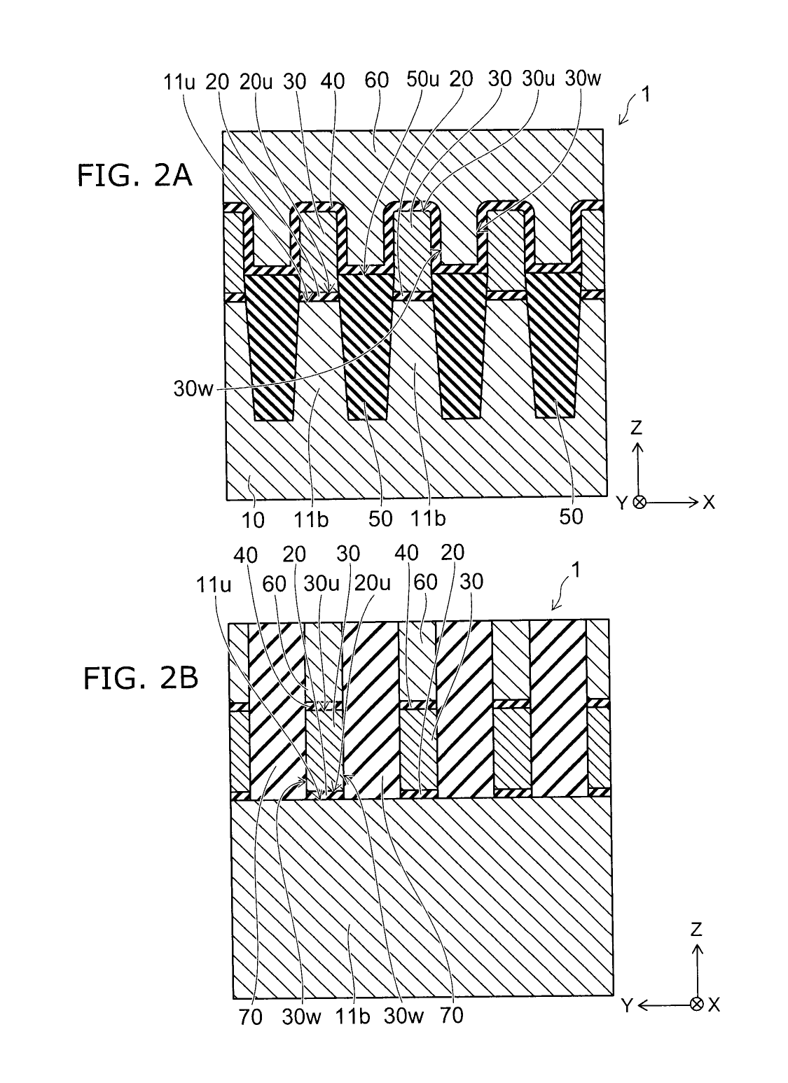

FIG. 2A and FIG. 2B are examples of schematic cross-sectional views of the nonvolatile semiconductor memory device of a nonvolatile semiconductor memory layer according to the embodiment.

FIG. 2A shows a cross section taken along line A-A′ of FIG. 1, and FIG. 2B shows a cross section taken along line B-B′ of FIG. 1.

As shown in FIG. 2A and FIG. 2B, the nonvolatile semiconductor memory device 1 includes a semiconductor substrate 10, the semiconductor region 11b, the control gate electrode 60, a charge storage layer 30, a gate insulating film 20, a gate insulating film 40, and the element isolation region 50.

The nonvolatile semiconductor memory device 1 includes a transistor that includes the semiconductor region 11b, the gate insulating film 20, the charge storage layer 30, the gate insulating film 40, and the control gate electrode 60 in a position where the semiconductor region 11b and the control gate electrode 60 cross each other. The charge storage layer 30 may be an insulating film having a trap level, or a stacked film of a conductive film and an insulating film having a trap level.

Each of the semiconductor regions 11b is partitioned by the element isolation region 50 in the semiconductor substrate 10. Upper portions of the semiconductor regions 11b are doped with an impurity, and function as active areas that are parts of the transistors of the nonvolatile semiconductor memory device 1.

The gate insulating film 20 is provided between the charge storage layer 30 and the semiconductor regions 11b. The position of the upper surface 20u of the gate insulating film 20 is lower than the position of the upper surface 50u of the element isolation region 50. The gate insulating film 20 functions as a tunnel insulating film that allows a charge (e.g. electrons) to tunnel between the semiconductor region 11b and the charge storage layer 30.

The charge storage layer 30 is provided in a position where the semiconductor regions 11b and the control gate electrode 60 cross each other. The charge storage layer 30 covers the upper surface 20u of the gate insulating film 20. The charge storage layer 30 can store a charge that has tunneled from the semiconductor region 11b via the gate insulating film 20. The charge storage layer 30 may be referred to as a floating gate layer. The charge storage layer 30 is substantially a rectangle extending in the Z-direction in the A-A′ cross section and the B-B′ cross section shown in FIGS. 2A and 2B. Therefore, the charge storage layer 30 extends substantially in a columna shape in the Z-direction.

The gate insulating film 40 is provided between the charge storage layer 30 and the control gate electrodes 60. The gate insulating film 40 covers the upper surface 30u of the charge storage layer 30. For example, in the X-direction, the gate insulating film 40 covers portions of the charge storage layer 30 other than the portion where the element isolation region 50 is in contact with the charge storage layer 30. In other words, in the X-direction, the gate insulating film 40 covers part of the side surface 30w of the charge storage layer 30. In the X-direction, the side surface 30w of the charge storage layer 30 is covered with an interlayer insulating film 70.

The upper surface 30u and the side surface 30w of the charge storage layer 30 are covered with an insulator, and the charge stored in the charge storage layer 30 is prevented from leaking to the control gate electrode 60. The gate insulating film 40 may be referred to as a charge block layer.

The element isolation region 50 is provided between semiconductor regions 11b. The element isolation region 50 is in contact with a side surface of the gate insulating film 20 and part of the charge storage layer 30. The position of the upper surface 50u of the element isolation region 50 is lower than the position of the upper surface 30u of the charge storage layer 30. The position of the upper surface 11u of the semiconductor region 11b is lower than the position of the upper surface 50u of the element isolation region 50.

The control gate electrode 60 covers part of the charge storage layer 30 via the gate insulating film 40. For example, in the X-direction, the control gate electrode 60 covers the upper surface 30u and part of the side surface 30w of the charge storage layer 30 via the gate insulating film 40. In the Y-direction, the control gate electrode 60 covers the upper surface 30u of the charge storage layer 30 via the gate insulating film 40. The control gate electrode 60 functions as a gate electrode for controlling the transistor. An interlayer insulating film is provided on the control gate electrode 60 (not shown).

The material of the semiconductor substrate 10 is a p-type silicon crystal, for example. The material of the semiconductor regions 11a and 11b is an n-type semiconductor crystal, for example.

The material of the gate insulating film 20 is silicon oxide (SiO₂), silicon nitride (Si₃N₄), or the like, for example. The gate insulating film 20 may be a single layer of a silicon oxide film or a silicon nitride film, or a film in which either a silicon oxide film or a silicon nitride film is stacked, for example.

The material of the charge storage layer 30 is a semiconductor doped with a p-type impurity, a metal, a metal compound, or the like, for example. As the material of the charge storage layer 30, for example, amorphous silicon (a-Si), polysilicon (poly-Si), silicon germanium (SiGe), silicon nitride (SiₓN_{y}), hafnium oxide (HfOₓ), and the like are given.

The gate insulating film 40 may be a single layer of a silicon oxide film or a silicon nitride film, or a film in which either a silicon oxide film or a silicon nitride film is stacked, for example. For example, the gate insulating film 40 may be what is called an ONO film (silicon oxide film/silicon nitride film/silicon oxide film). The gate insulating film 40 may be also a metal oxide film or a metal nitride film.

The material of the element isolation region 50 and the interlayer insulating film 70 is silicon oxide (SiO₂), for example. Other than these, in the embodiment, portions written as insulating layers and insulating films contain silicon oxide (SiO₂), silicon nitride (Si₃N₄), or the like, for example.

The material of the control gate electrode 60 is a semiconductor containing a p-type impurity, for example. Polysilicon is given as the semiconductor. Alternatively, the material of the control gate electrode 60 may be a metal such as tungsten or a metal silicide, for example.

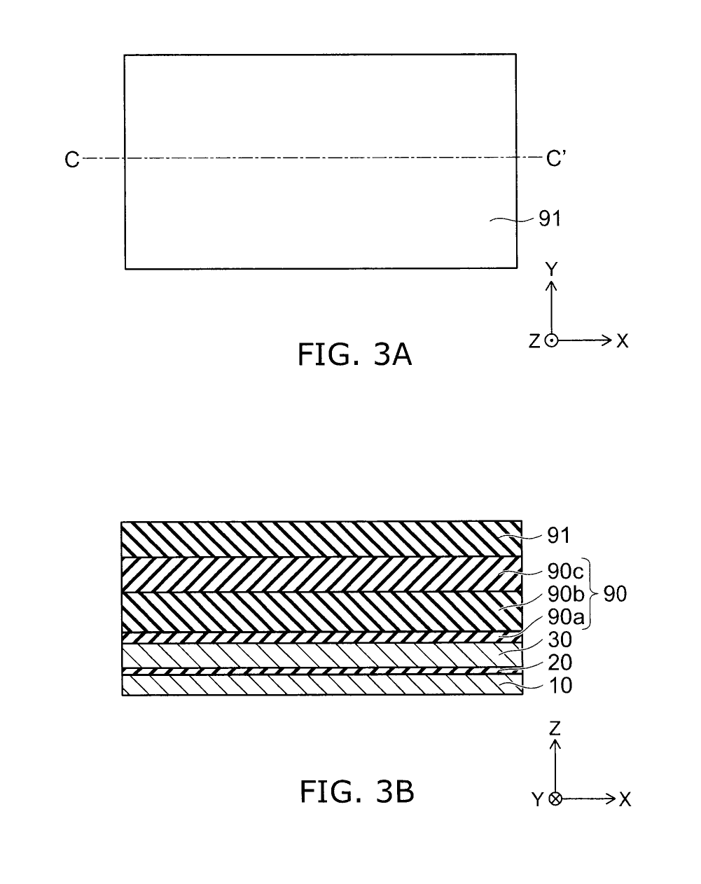

FIG. 3A to FIG. 16B are examples of schematic views showing the manufacturing process of the nonvolatile semiconductor memory device according to the embodiment.

Here, the drawings of the numbers including “A” of FIG. 3A to FIG. 16B show schematic plan views corresponding to FIG. 1. The drawings of the numbers including “B” of FIG. 3A to FIG. 16B show a cross section taken along line C-C′ of the drawings of the numbers including “A” of FIG. 3A to FIG. 16B.

As shown in FIG. 3A and FIG. 3B, the gate insulating film 20, the charge storage layer 30, a mask layer 90, and a mask layer 91 are formed in this order on the semiconductor substrate 10 by CVD (chemical vapor deposition).

The mask layer 90 includes a silicon nitride film 90a, a silicon oxide film 90b formed on the silicon nitride film 90a, and a polysilicon film 90c formed on the silicon oxide film 90b, for example. The mask layer 91 is a silicon oxide film, for example.

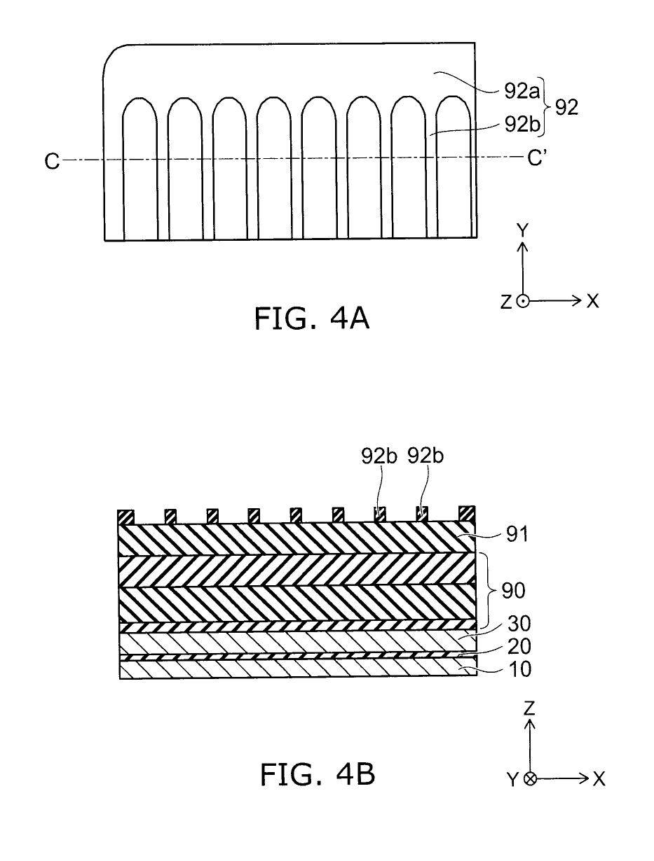

Next, as shown in FIG. 4A and FIG. 4B, a mask layer 92 is formed on the mask layer 90 by photolithography and etching. The mask layer 92 is a photoresist.

The mask layer 92 has a pattern region 92a extending in the X-direction and pattern regions 92b. The pattern regions 92b extend in the Y-direction from the pattern region 92a, and are arranged at certain intervals in the X-direction. An end portion in the Y-direction of the pattern region 92a is connected to the pattern region 92a.

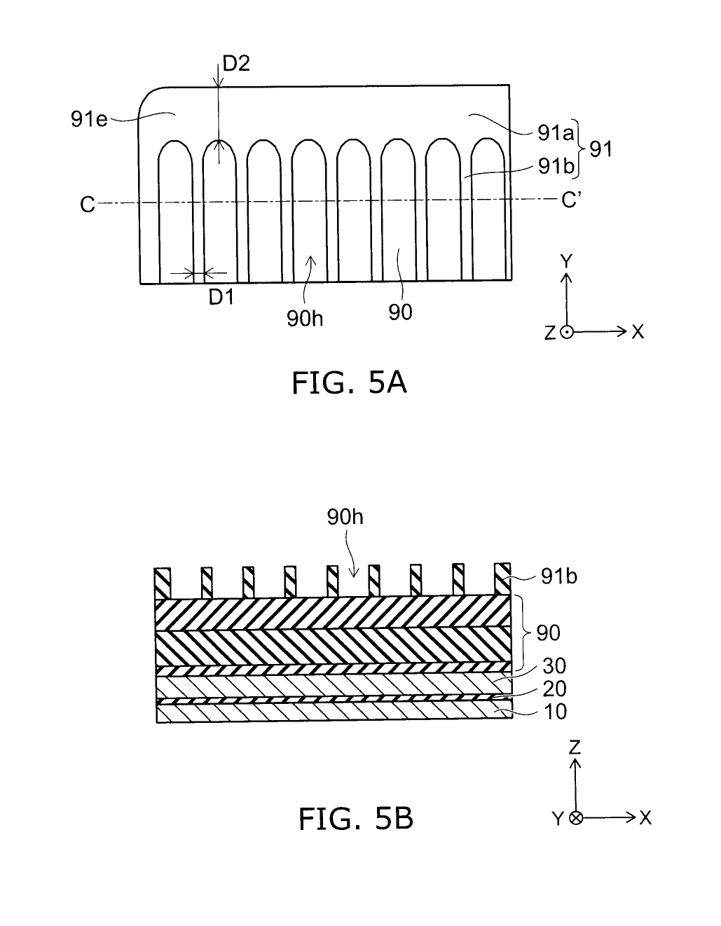

Next, as shown in FIG. 5A and FIG. 5B, the mask layer 92 is used as a mask to perform dry etching (e.g. RIE (reactive ion etching)) on the mask layer 91. As a result, a mask layer 91 having the pattern of the mask layer 92 is formed above the mask layer 90.

The mask layer 91 has openings 90h extending in the Y-direction and arranged with a first spacing D1 in the X-direction crossing the Y-direction. The width D2 from the opening 90h to an end 91e in the Y-direction is wider than the first spacing D1. After that, the mask layer 92 is removed using ashing technique. The first spacing D1 may be regarded as the width in the X-direction of a pattern region 91b. The first spacing D1 is almost equal to the width Wb. At this time, a sliming process may be paformed to adjust so that the first spacing D1 is brought close to the width Wb.

The mask layer 91 has a pattern region 91a extending in the X-direction and pattern regions 91b. The plurality of pattern regions 91b extend in the Y-direction from the pattern region 91a, and are arranged in the X-direction. An end portion in the Y-direction of the pattern region 91a is connected to the pattern region 91a.

Next, the pattern regions 91b are used as a mandrel to form a mask layer with a smaller pitch than the pattern regions 91b by what is called double patterning technology.

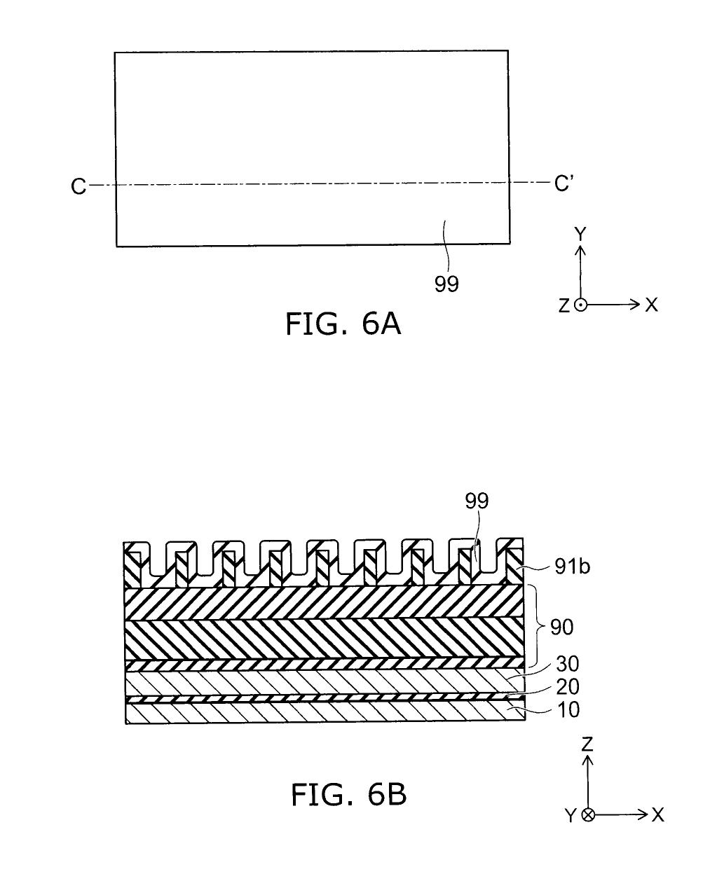

For example, as shown in FIG. 6A and FIG. 6B, a mask layer 99 is formed on the mask layer 90 and on the mask layer 91 by CVD. The mask layer 99 includes a silicon nitride film, for example. After that, processing is performed by anisotropic RIE processing until the upper end of the pattern region 91b is exposed, for example.

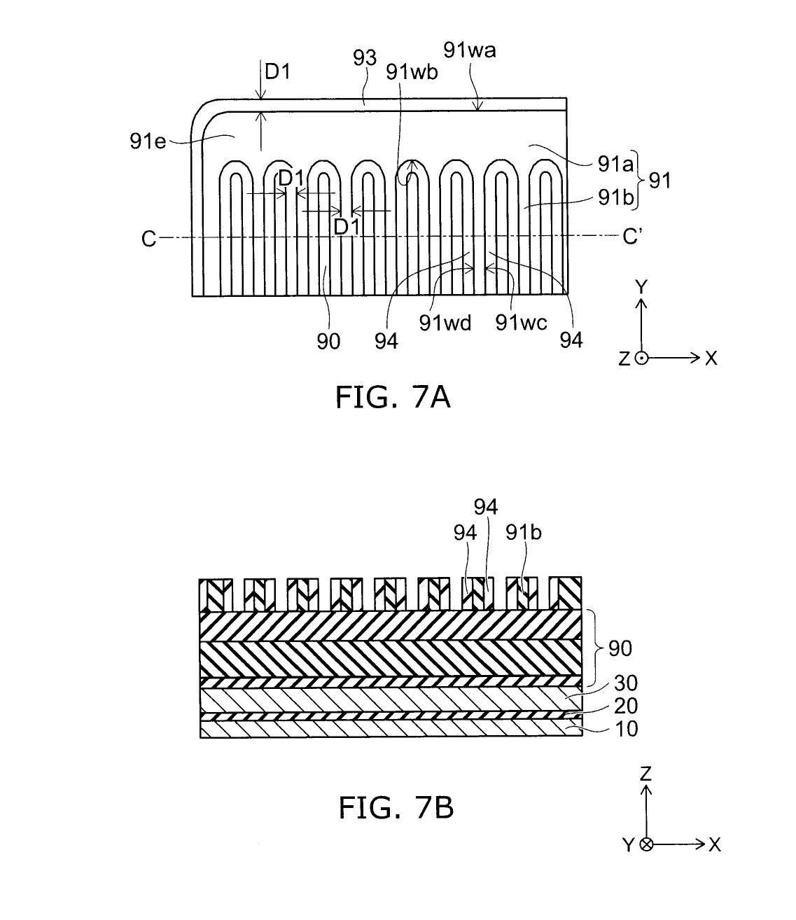

In the RIE processing, as shown in FIG. 7A and FIG. 7B, processing is performed so that the mask layer 99 remains on the side surface 91wa of the pattern region 91a and on the side surface 91wb on the opposite side to the side surface 91wa. At the same time, processing is performed so that the mask layer 99 remains on the side surface 91wc of the pattern regions 91b and on the side surface 91wd on the opposite side to the side surface 91wc.

Thereby, the mask layer 99 is processed and a ring-like mask layer 94 is formed in the opening 90h of the mask layer 91. A mask layer 93 is formed on the side surface 91wa of the end 91e. The mask layer 94 has a portion extending in the X-direction and a portion extending in the Y-direction.

The width of the mask layers 93 and 94 is 20 nm or less, for example. The length in the Y-direction of the pattern region 91a is approximately 200 nm. The length of the portion extending in the Y-direction of the mask layer 93 is the same as the width in the X-direction of the mask layer 94.

That is, in the X-direction, the width of the opening 90h is approximately three times the first spacing D1, and the width of the mask layers 93 and 94 is almost equal to the first spacing D1.

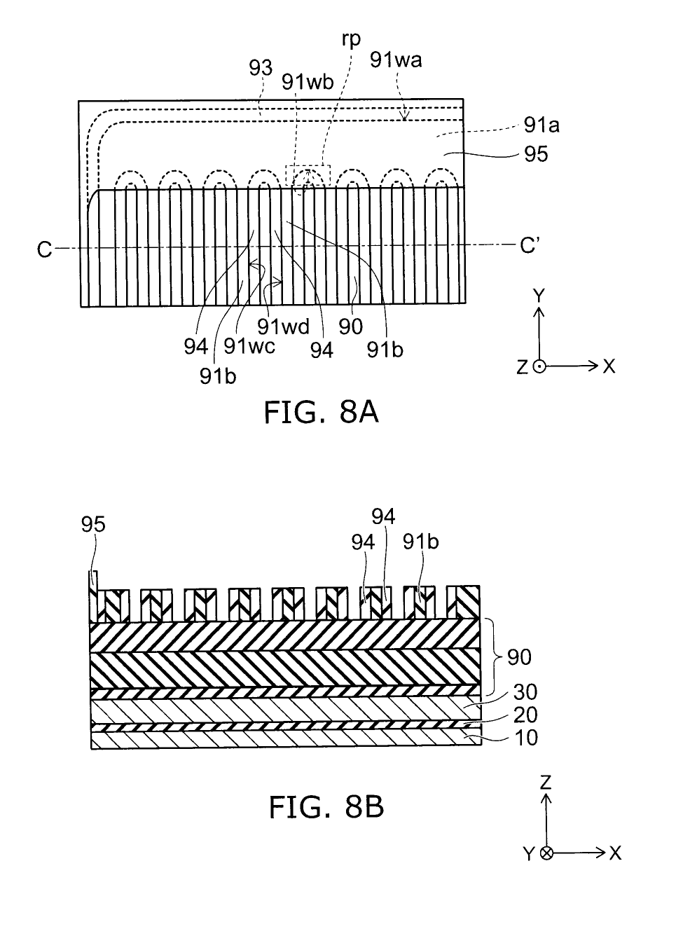

Next, as shown in FIG. 8A and FIG. 8B, a mask layer 95 is formed that covers the mask layer 93 in contact with the side surface 91wa, the pattern region 91a, and a loop region rp in which the side surface 91wb and the mask layer 94 in contact with the side surface 91wb. In other words, a mask layer 95 that covers at least part of the mask layer 93 and part of the end portion in the Y-direction of the mask layer 94 (the loop region rp) is formed. The width in the Y-direction of the mask layer 95 is wider than the first spacing D1 mentioned earlier. In the Y-direction, an end portion of the mask layer 95 is located on a side of the mask layer 94 extending in the Y-direction of the ring-like mask layer 94. The mask layer 95 completely covers the portion extending in the X-direction of the mask layer 93.

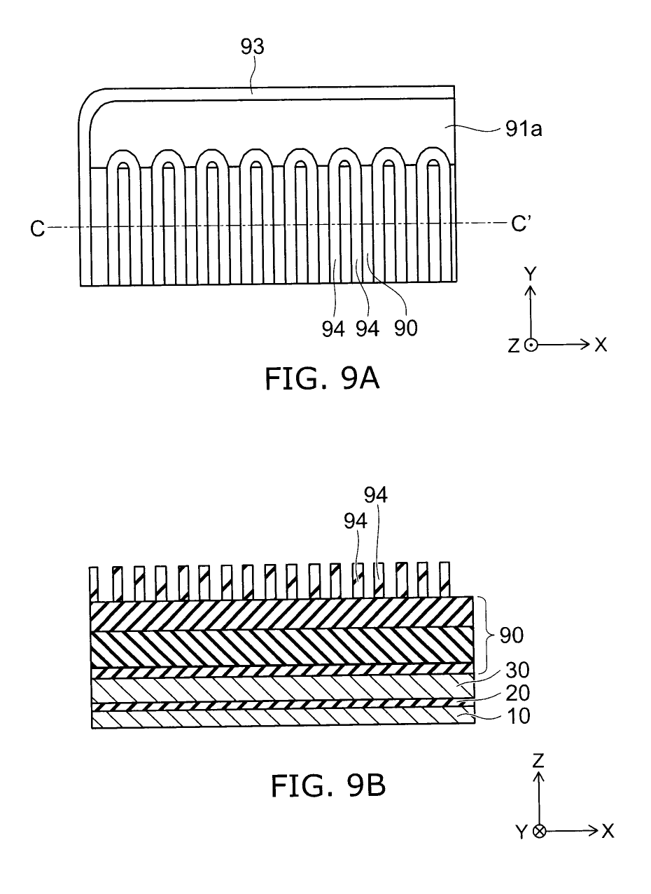

Next, as shown in FIG. 9A and FIG. 9B, the pattern region 91b (part of the mask layer 91) exposed from the mask layer 95 is removed by wet etching. In the wet etching, a hydrofluoric acid solution is used, for example. After that, the mask layer 95 is removed by, for example, a sulfated aqueous solution. As a result, the pattern region 91a is formed in a portion of the mask layer 91 that was covered with the mask layer 95.

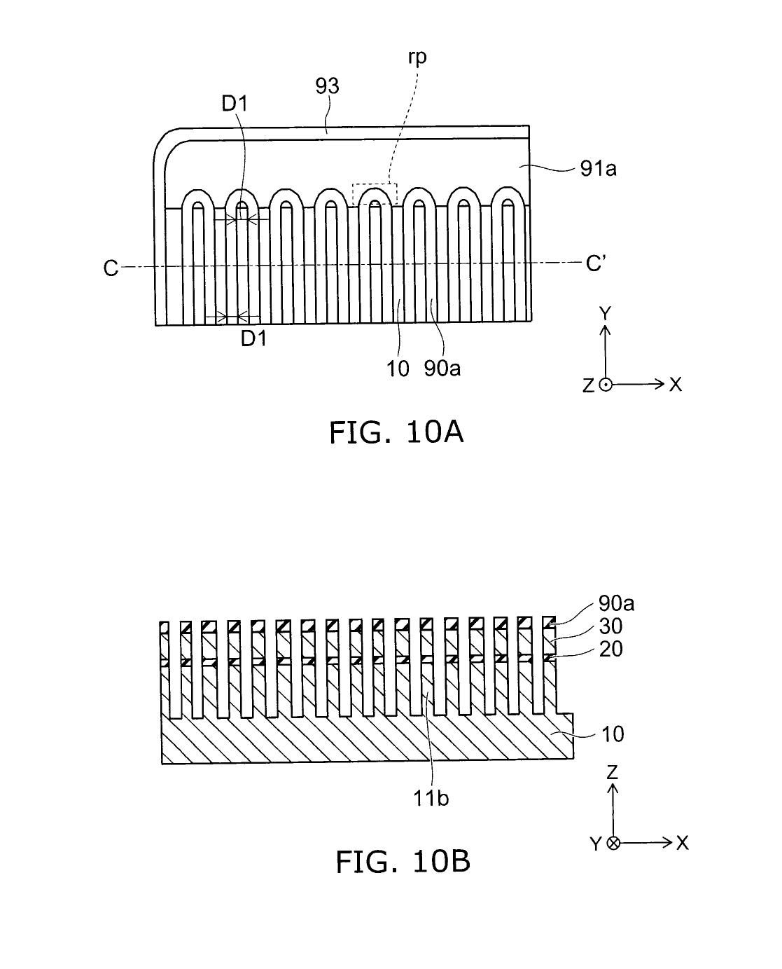

Next, as shown in FIG. 10A and FIG. 10B, the mask layer 90 is processed by RIE method using the mask layer 93, the mask layer 94, and the pattern region 91a (part of the mask layer 91) as a mask. After that, the mask layer 94, 93, and the pattern region 91a are removed. Subsequently, the charge storage layer 30, the gate insulating film 20 under the charge storage layer 30, and upper portions of the semiconductor substrate 10 under the gate insulating film 20 are removed by RIE method using the mask layer 90. In the RIE, the mask layer 94 and an upper portion of the mask layer 90 may be eliminated to expose the upper end of the silicon nitride film 90a.

Thereby, stacked bodies 15 are formed that include the semiconductor region 11b, the gate insulating film 20 formed on the semiconductor region 11b, and the charge storage layer 30 formed on the gate insulating film 20. The stacked bodies 15 extend in the Y-direction, and are arranged with the first spacing D1 in the X-direction. The width in the X-direction of the stacked bodies 15 is almost equal to the first spacing D1.

After the trench is formed in the semiconductor substrate 10 by RIE method, the pattern of the loop region rp is transferred also to the semiconductor substrate 10; but the transferred loop region of the semiconductor substrate 10 may be removed.

The charge storage layer 30, the gate insulating film 20, and the upper portion of the semiconductor substrate 10 under the mask layer 90 having been covered with the mask layer 93, 94 and the pattern region 91a are not removed by the RIE. In other words, trenches extending in the Y-direction and arranged in the X-direction are formed between stacked bodies 15. After that, the mask layer 90 is removed.

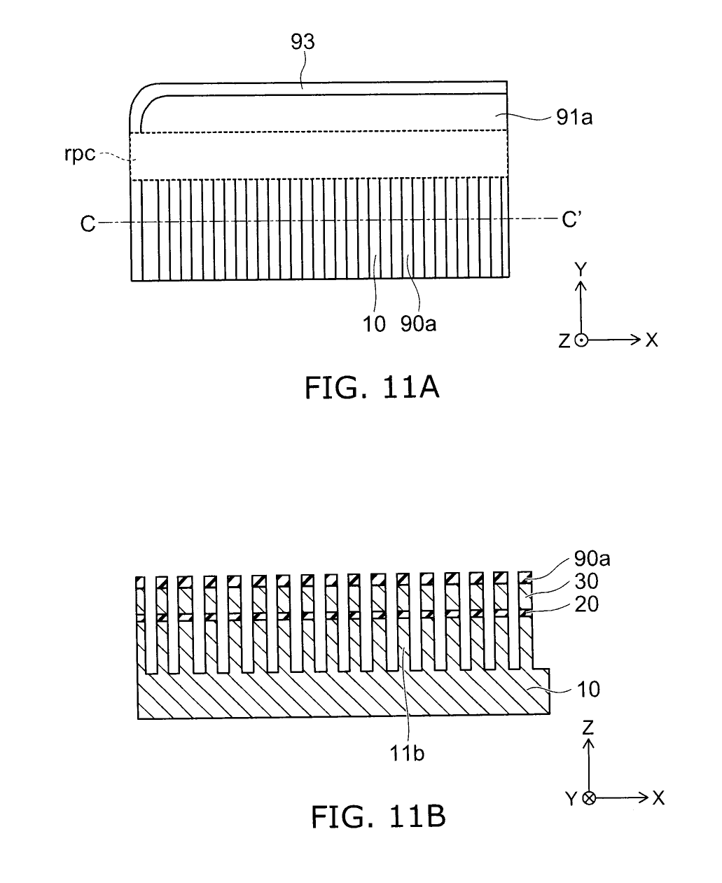

As show in FIG. 11A and FIG. 11B, what is called loop cutting may be performed as necessary. For example, a mask having an opening rpc on a portion extending in the X-direction of the ring-like stacked body 15 is formed, and this mask is used to perform RIE to remove the charge storage layer 30, the gate insulating film 20, and the upper portion of the semiconductor substrate 10. As a result, each ring-like stacked body 15 is separated into two stacked bodies 15 extending in the Y-direction.

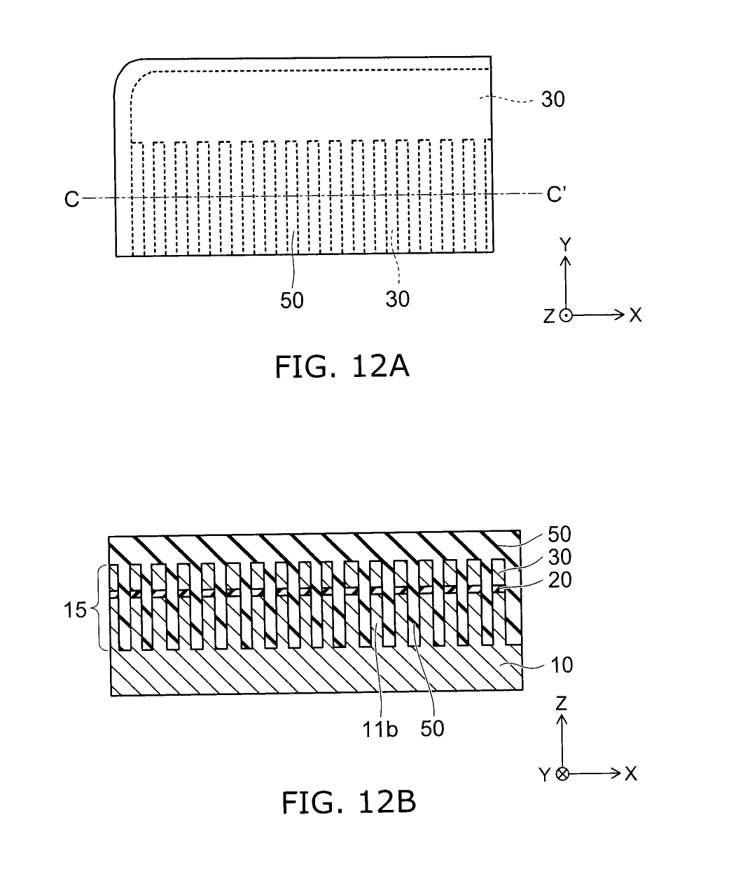

Next, as shown in FIG. 12A and FIG. 12B, the element isolation region 50 is formed between adjacent stacked bodies 15. The processes after FIG. 12A and FIG. 12B are described using the case where loop cutting is not performed, as an example.

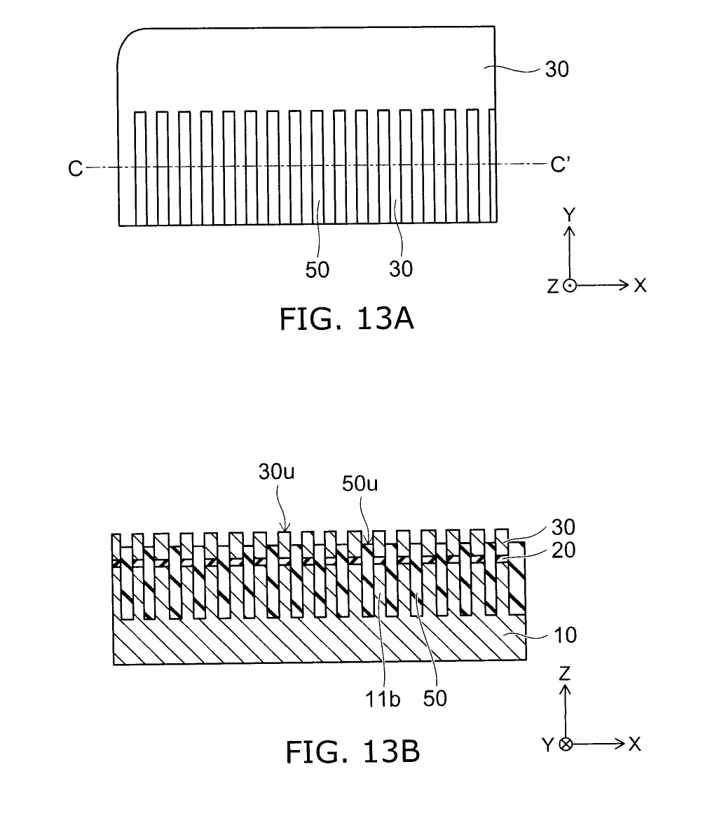

Next, as shown in FIG. 13A and FIG. 13B, the upper surface 50u of the element isolation region 50 is lowered by etchback so that the upper surface 50u of the element isolation region 50 is located lower than the upper surface 30u of the charge storage layer 30.

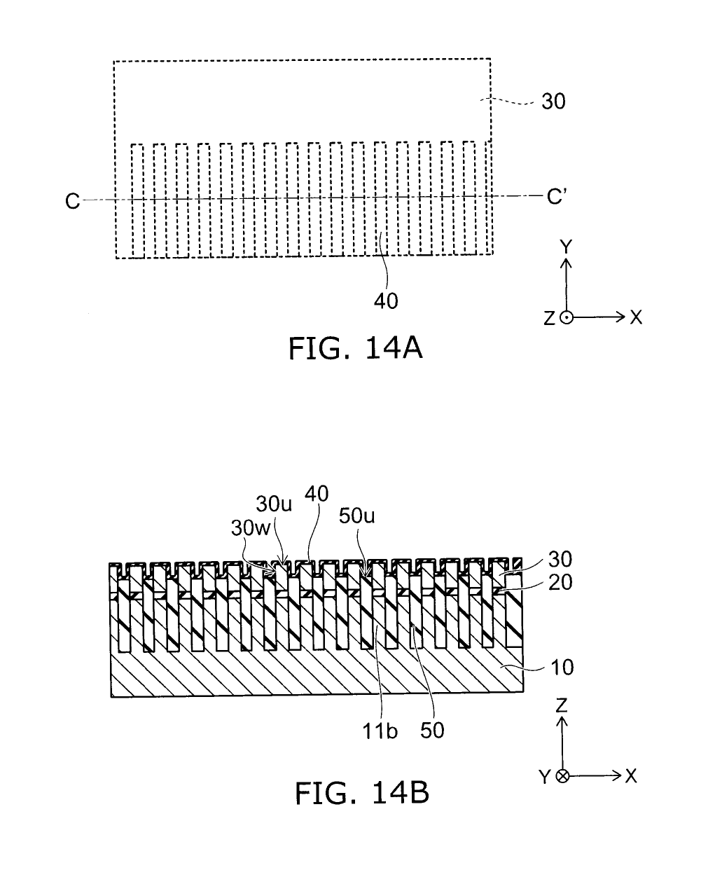

Next, as shown in FIG. 14A and FIG. 14B, the gate insulating film 40 is formed that is in contact with the upper surface 30u of the charge storage layer 30, part of the side surface 30w of the charge storage layer 30, and the upper surface 50u of the element isolation region 50.

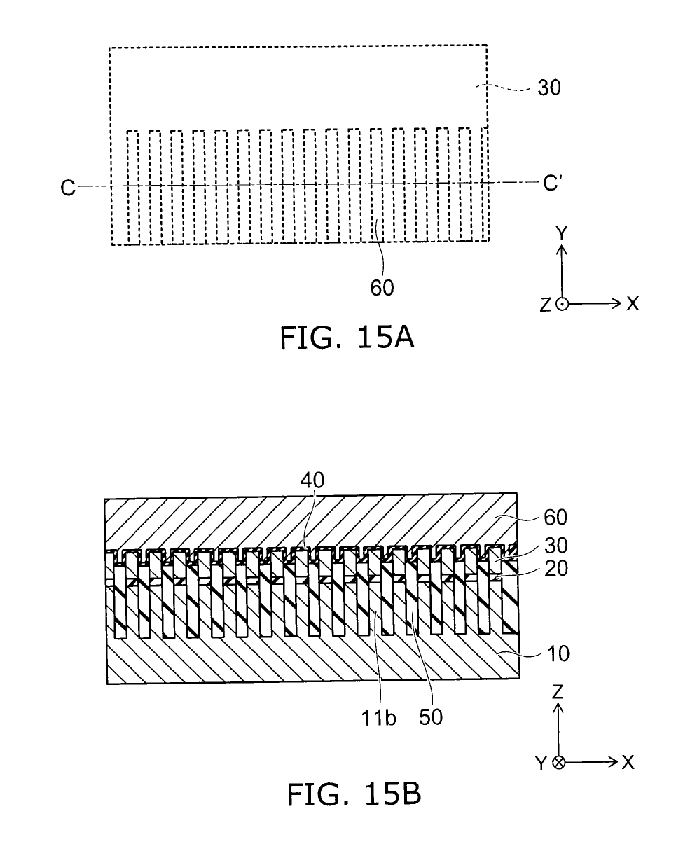

Next, as shown in FIG. 15A and FIG. 15B, a gate electrode layer 60 is formed on the gate insulating film 40.

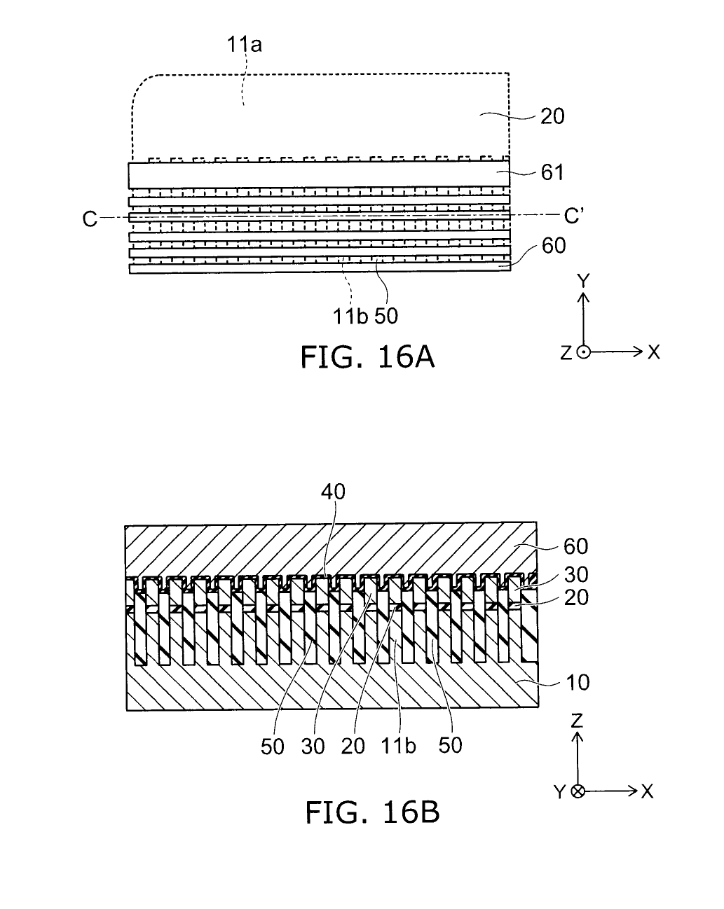

Next, as shown in FIG. 16A and FIG. 16B, a mask layer extending in the X-direction and aligned in the Y-direction is formed above the gate electrode layer 60, and etching is performed to remove the gate electrode layer 60 exposed from the mask layer, the gate insulating film 40 under the gate electrode layer 60, and the charge storage layer 30 under the gate insulating film 40. Thereby, the control gate electrode 60 crossing the semiconductor region 11b and the select gate electrode 61 are formed.

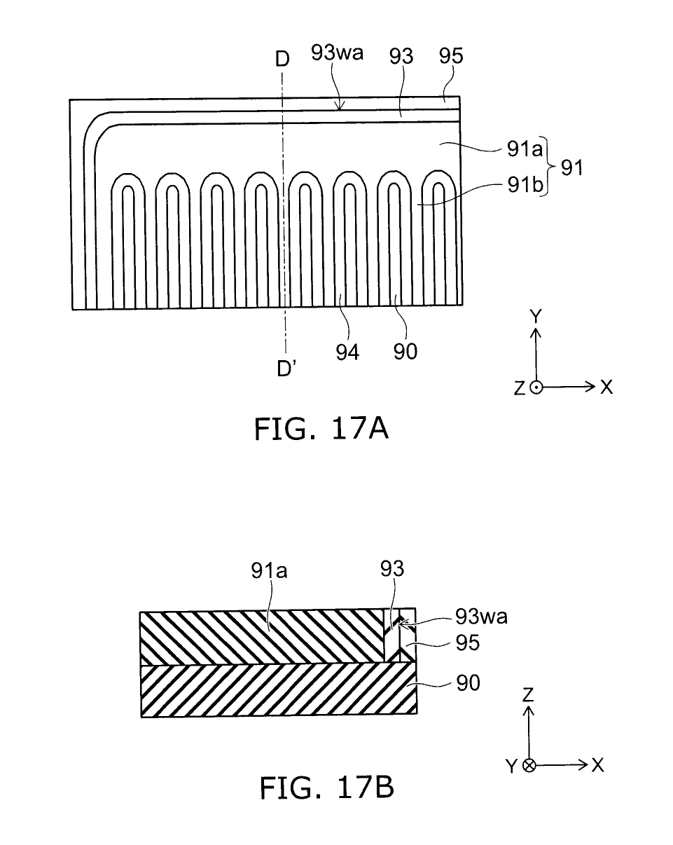

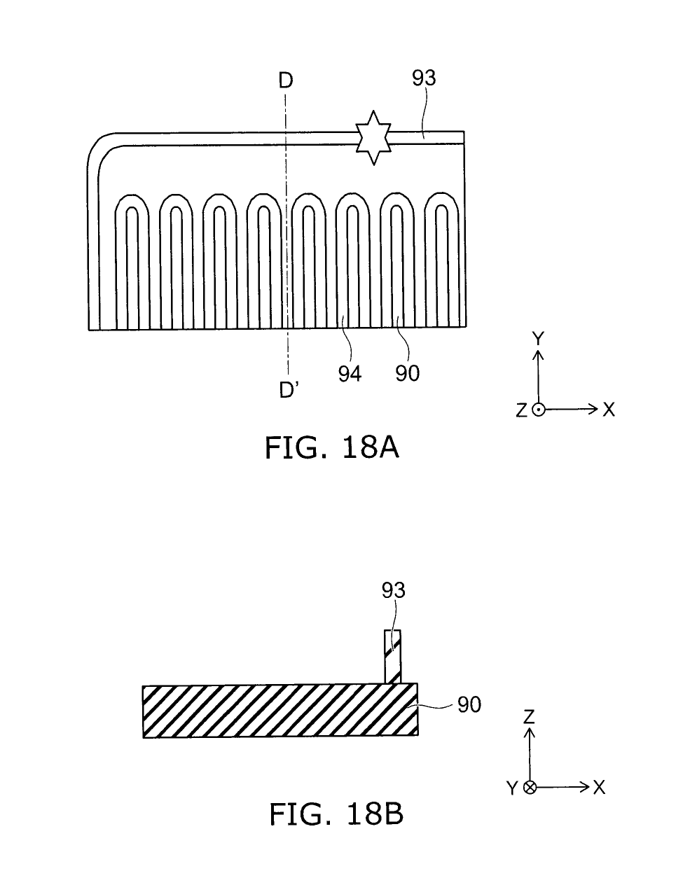

FIG. 17A to FIG. 18B are examples of schematic views showing the manufacturing process of a nonvolatile semiconductor memory device according to a comparative example.

Here, the drawings of the numbers including “A” of FIG. 17A to FIG. 18B show schematic plan views corresponding to the regions of the semiconductor regions 11a and 11b shown in FIG. 1. The drawings of the numbers including “B” of FIG. 17A to FIG. 18B show a cross section taken along line D-D′ of the drawings of the numbers including “A” of FIG. 17A to FIG. 18B.

The mask layer 95 is formed in FIG. 8A and FIG. 8B described above.

However, in FIG. 17A and FIG. 17B, the mask layer 95 like that shown in FIG. 8A and FIG. 8B is not formed and the processing shown in FIG. 9A to FIG. 10B is performed.

FIG. 18A and FIG. 18B show a state after the mask layer 91 is removed by wet etching from the state shown in FIGS. 17A and 17B.

Here, the width in the Y-direction of the mask layer 93 is 20 nm or less, for example, and the length in the X-direction thereof may be up to 5 mm or more, for example. Therefore, the isolated mask layer 93 does not have sufficient mechanical strength, and may fall down or divide during the wet etching. Furthermore, pieces of the mask layer 93 that has fallen down may scatter and become contaminants (foreign substances) to adversely inpact the manufacturing process and characteristics of the nonvolatile semiconductor memory device. Similarly, if the mask layer 93 is used as a mask, the stacked body 15 is formed under the mask layer 93. The width of the stacked body 15 is equal to the width of the mask layer 93. That is, also the stacked body 15 formed under the mask layer 93 may fall down.

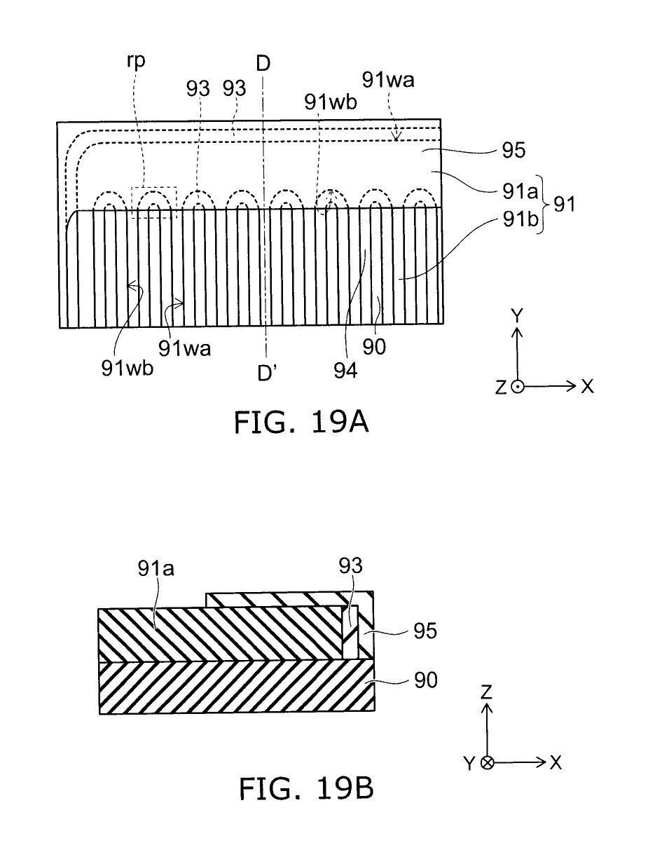

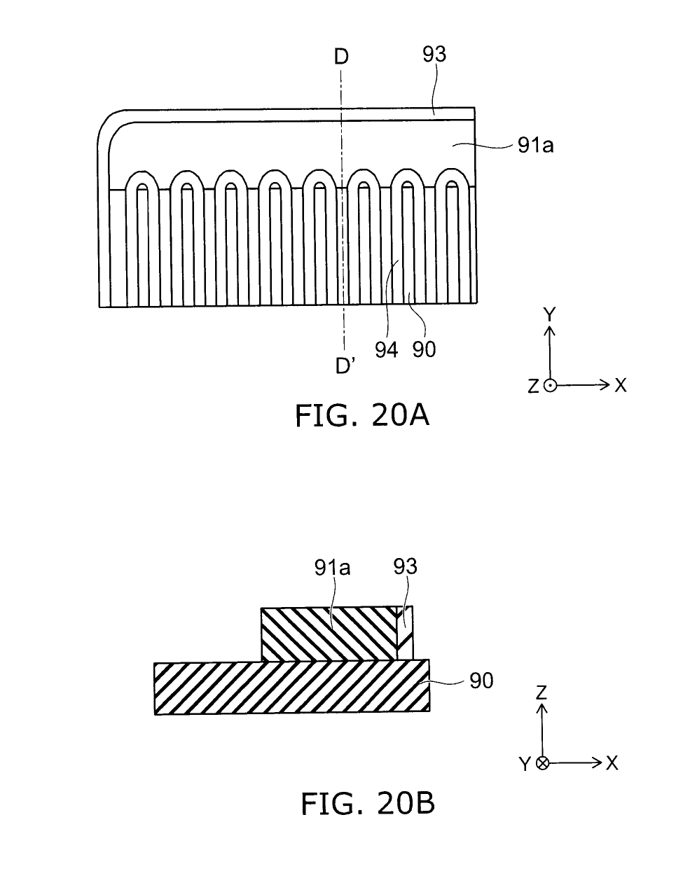

FIG. 19A to FIG. 20B are examples of schematic views showing effects of the manufacturing process of the nonvolatile semiconductor memory device according to the embodiment.

Here, the drawings of the numbers including “A” of FIG. 19A to FIG. 20B show schematic plan views corresponding to FIG. 1. The drawings of the numbers including “B” of FIG. 19A to FIG. 20B show a cross section taken along line D-D′ of the drawings of the numbers including “A” of FIG. 19A to FIG. 20B.

In contrast, in the embodiment, as shown in FIG. 19A and FIG. 19B, the mask layer 95 is formed that covers the mask layer 93 in contact with the side surface 91wa of the mask layer 91, the pattern region 91a, and the loop region rp in which the side surface 91wc and the mask layer 94 in contact with the side surface 91wc and the side surface 91wd are joined.

From such a state, the mask layer 91 (the pattern region 91b) exposed from the mask layer 95 is removed by wet etching using a hydrofluoric acid solution, and the mask layer 95 is removed by, for example, a sulfated aqueous solution. FIG. 20A and FIG. 20B show this state.

In the embodiment, the mask layer 93 is in contact with the pattern region 91a. That is, the mask layer 93 is supported by the pattern region 91a, and thus the mechanical strength of the mask layer 93 is reinforced by the pattern region 91a. Therefore, the mask layer 93 is less likely to fall down or divide during wet etching. Thus, there is no possibility that pieces of the mask layer 93 that has fallen down will become contaminants (foreign substances). Consequently, the embodiment provides a highly reliable nonvolatile semiconductor memory device. Furthermore, the manufacturing yield of nonvolatile semiconductor memory devices is improved.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a first semiconductor region extending in a first direction;
second semiconductor regions extending in a second direction crossing the first direction from the first semiconductor region and arranged in the first direction; and
a first element isolation region provided between the second semiconductor regions;
a width of the first semiconductor region in the second direction being wider than a width of the second semiconductor region in the first direction.

2. The device according to claim 1, wherein a width of the second semiconductor region in the first direction is smaller than a resolution limit of lithography.

3. The device according to claim 1, wherein, in the first direction, ends of the second semiconductor regions are located in the same position.

4. A method for manufacturing a semiconductor memory device comprising:
forming a first mask layer and a second mask layer above a semiconductor substrate;
forming the second mask layer into a pattern having openings extending in a first direction and arranged with a first spacing in a second direction crossing the first direction, a width from the opening to an end of the pattern in the first direction being wider than the first spacing;
forming a third mask layer in the opening of the second mask layer and forming a fourth mask layer on a side surface of the second mask layer opposite side to the opening;
forming a fifth mask layer covering at least part of the fourth mask layer and part of an end portion in the first direction of the third mask layer;
removing the second mask layer using the fifth mask layer as a mask;
processing the first mask layer using the fifth mask layer and the second mask layer as a mask;
forming a trench by processing the semiconductor substrate using the first mask layer; and
burying an insulating film in the trench.

5. The method according to claim 4, further comprising removing a portion where the first mask layer is joined in the first direction, after the processing the first mask layer.

6. The method according to claim 4, further comprising removing a portion where the semiconductor substrate is joined in the first direction, after the forming a trench in the semiconductor substrate.

7. The method according to claim 4, wherein a width of the third mask layer in the second direction is equal to the first spacing.

8. The method according to claim 4, wherein a width of the fifth mask layer in the first direction is wider than the first spacing.

9. The method according to claim 4, wherein the third mask layer has ring-like shape and an end portion of the fifth mask layer on the opening side in the first direction is located on an extending in the second direction of the third mask layer.

10. The method according to claim 4, wherein the fourth mask layer has a first portion extending in the first direction and a second portion extending in the second direction.

11. The method according to claim 10, wherein a width of the first portion of the fourth mask layer is the same as a width in a second direction of the third mask layer.

12. The method according to claim 10, wherein the fifth mask layer completely covers the first portion of the fourth mask layer.
